(19) United States
(12) Patent Application Publication
(10) Pub. No.: US 2025/0024609 A1
(43) Pub. Date: Jan. 16, 2025

(54) WIRING-FORMING MEMBER, WIRING LAYER FORMING METHOD USING WIRING-FORMING MEMBER, AND WIRING-FORMED MEMBER

(71) Applicant: Resonac Corporation, Tokyo (JP)

(72) Inventors: Masashi OHKOSHI, Tokyo (JP); Yuka ITOH, Tokyo (JP); Shunsuke TAKAGI, Tokyo (JP); Kunihiko AKAI, Tokyo (JP); Nozomu TAKANO, Tokyo (JP); Hiroyuki IZAWA, Tokyo (JP); Daisuke FUJIMOTO, Tokyo (JP); Tomohiko KOTAKE, Tokyo (JP)

(21) Appl. No.: 18/713,272

(22) PCT Filed: Nov. 28, 2022
(86) PCT No.: PCT/JP2022/043815

§ 371 Date: Jul. 31, 2024

(30) Foreign Application Priority Data
Nov. 29, 2021 (JP) 2021-192723

(51) Int. Cl. H05K 3/38

(52) U.S. Cl. CPC H05K 3/38

(57) ABSTRACT

A wiring-forming member 1 includes an adhesive layer 10 containing conductive particles 12, and a metal layer 20 disposed on the adhesive layer 10. The adhesive layer 10 includes a first adhesive layer 15 containing the conductive particles 12 and an adhesive component, and a second adhesive layer 16 containing an adhesive component.

### TECHNICAL FIELD

The present disclosure relates to a wiring-forming member, a wiring layer forming method using the wiring-forming member, and a wiring-formed member.

### BACKGROUND ART

In Patent Literature 1, a production method for a printed-wiring board in which an electronic component such as an IC chip is built is disclosed.

### CITATION LIST

### Patent Literature

Patent Literature 1: Japanese Unexamined Patent Publication No. 2012-191204

### SUMMARY OF INVENTION

### Technical Problem

In a production method for a substrate with a built-in component of the related art, as illustrated in (a) and (b) in FIG. 10, insulating resin layers 102 and 103 are formed on both sides of an electronic component 101 on which an electrode 101a is provided in a lamination direction. After that, as illustrated in (c) and (d) in FIG. 10, boring a hole by laser, forming an electrode or wiring by forming and etching a plating layer, or the like is performed to form via electrodes 104 and 105 reaching each electrode 101a of the electronic component 101 in each of the insulating resin layers 102 and 103. Then, as illustrated in (a) to (c) in FIG. 11, forming insulating resin layers 106 and 107, forming a via electrode 108 by boring a hole by laser and forming a plating layer, and forming an electrode or wiring by etching, or the like is further repeated to form a substrate 110 with a built-in component. Note that, the wiring formed on the insulating resin layer of the substrate with a built-in component, as illustrated in (c) in FIG. 11, includes not only a portion 109 conductively connected by a conductive layer but also a portion 109a not conductively connected in the lamination direction, and is designed with various patterns in accordance with the configuration of the substrate with a built-in component.

In the production method for the substrate with a built-in component, one conductive layer (via electrode) is formed by performing many treatments, and it is necessary to repeat such treatments to form a plurality of conductive layers, which makes a production process extremely complicated.

Therefore, an object of the present disclosure is to provide a wiring-forming member capable of simplifying a process of forming a wiring layer connecting wirings while sufficiently ensuring the degree of freedom in the design of a wiring pattern, a wiring layer forming method using the wiring-forming member, and a wiring-formed member.

### Solution to Problem

As one aspect, the present disclosure relates to a wiring-forming member. A first wiring-forming member is a wiring-forming member including an adhesive layer containing conductive particles, and a metal layer disposed on the adhesive layer, in which the adhesive layer includes a first adhesive layer containing the conductive particles and an adhesive component, and a second adhesive layer containing an adhesive component. In addition, a second wiring-forming member is a wiring-forming member including an adhesive layer containing conductive particles, and a metal layer disposed on the adhesive layer, in which the adhesive layer, in a thickness direction thereof, includes a first region containing the conductive particles and a first adhesive component, and a second region containing a second adhesive component.

According to the first and second wiring-forming members described above, by the adhesive layer including the first adhesive layer or the first region, it is possible to obtain electrical conduction between a wiring pattern or the metal layer to be wiring and another wiring pattern or wiring to adhere through the adhesive layer after processing, and simplify a process of forming a wiring layer connecting wirings compared to the process of the related art in which laser processing, a filled plating treatment, and the like are performed. In addition, by the adhesive layer including the second adhesive layer or the second region, even in a case where the wiring layer formed by patterning the metal layer includes a portion in a lamination direction (or the thickness direction of the adhesive layer), in which conductive connection is not desired, it is easy to ensure insulating reliability in the portion. In addition, in a case where a substrate on which the wiring is to be formed by the wiring-forming member has large irregularities (for example, in a case where the height of an electrode is large), it is possible to ensure embeddability by the second adhesive layer or the second region and prevent the occurrence of air bubbles or peeling. Therefore, according to the wiring-forming member described above, it is possible to sufficiently ensure the degree of freedom in the design of the wiring pattern when forming the wiring layer, and it is also possible to form complicated wiring with higher definition.

In the first wiring-forming member described above, the metal layer, the second adhesive layer, and the first adhesive layer may be laminated in this order. In addition, in the second wiring-forming member described above, the metal layer, the second region, and the first region may be provided adjacent to each other in this order. In such a case, in the wiring layer formed by patterning the metal layer or redistribution separately formed, the conductive particles are less likely to be in contact with a portion other than a portion conductively connected, and a transmission loss of the wiring due to the contact of the conductive particles is likely to be suppressed.

In the first wiring-forming member described above, the second adhesive layer may not contain conductive particles. In addition, in the second wiring-forming member described above, the second region may not contain conductive particles.

In the first and second wiring-forming members described above, a ratio of surface roughness Rz of a surface of the metal layer on the adhesive layer side to an average particle diameter of the conductive particles may be 0.05 to 3. In this case, it is possible to more reliably deform the conductive particles of the metal layer into a flattened shape, and make the electrical conduction between the wiring pattern or the metal layer to be the wiring and another wiring pattern or wiring to adhere through the adhesive layer after processing more stable.

In the first and second wiring-forming members described above, the surface roughness Rz of the surface of the metal layer on the adhesive layer side may be less than 20 μm. In this case, it is possible to more reliably deform the conductive particles of the metal layer into the flattened shape, and make the electrical conduction between the wiring pattern or the metal layer to be the wiring and another wiring pattern or wiring to adhere through the adhesive layer after processing more stable.

In the first and second wiring-forming members described above, a peeling film may be further provided.

As another aspect, the present disclosure relates to a wiring-forming member in which an adhesive layer containing conductive particles and a metal layer are separately provided, and the adhesive layer is adherable to the metal layer at the time of use. In a third wiring-forming member, the adhesive layer includes a first adhesive layer containing the conductive particles and an adhesive component, and a second adhesive layer containing an adhesive component. In addition, in a fourth wiring-forming member, the adhesive layer, in a thickness direction thereof, includes a first region containing the conductive particles and a first adhesive component, and a second region containing a second adhesive component. In such a case, by the adhesive layer including the first adhesive layer or the first region, it is possible to obtain electrical conduction between a wiring pattern or the metal layer to be wiring and another wiring pattern or wiring to adhere through the adhesive layer after processing, and simplify a process of forming a wiring layer connecting wirings compared to the process of the related art in which laser processing, a filled plating treatment, and the like are performed. In addition, according to the wiring-forming member described above, by the adhesive layer including the second adhesive layer or the second region, even in a case where the wiring layer formed by patterning the metal layer includes a portion in a lamination direction (or the thickness direction of the adhesive layer), in which conductive connection is not desired, it is easy to ensure insulating reliability in the portion. In addition, in a case where a substrate on which the wiring is to be formed by the wiring-forming member has large irregularities (for example, in a case where the height of an electrode is large), it is possible to ensure embeddability by the second adhesive layer or the second region and prevent the occurrence of air bubbles. Therefore, according to the wiring-forming member described above, it is possible to sufficiently ensure the degree of freedom in the design of the wiring pattern when forming the wiring layer, and it is also possible to form complicated wiring with higher definition. Further, since the adhesive layer and the metal layer can be separately (as a set for the wiring-forming member) prepared, it is possible to improve the degree of freedom in the operation when producing the wiring layer using the wiring-forming member, such as selecting a wiring-forming member with a more optimum material configuration.

In the third wiring-forming member described above, the second adhesive layer may not contain conductive particles. In addition, in the fourth wiring-forming member described above, the second region may not contain conductive particles.

As still another aspect, the present disclosure relates to a method for forming a wiring layer using any of the wiring-forming members described above. Such a wiring layer forming method includes a step of preparing any of the wiring-forming members described above, a step of preparing a base material on which wiring is formed, a step of disposing the wiring-forming member on a surface of the base material on which the wiring is formed such that the adhesive layer faces the base material to cover the wiring, a step of thermocompression-bonding the wiring-forming member to the base material, and a step of performing a patterning treatment on the metal layer. According to such a forming method, it is possible to considerably simplify a processing process compared to the method of the related art. In addition, according to such a forming method, as described above, since the insulating reliability in the portion of the wiring layer, in which conductive connection is not desired, can be ensured and/or the transmission loss of the wiring layer can be suppressed, or the occurrence of the air bubbles in a case where the substrate on which the wiring is to be formed by the wiring-forming member has large irregularities (for example, in a case where the height of the electrode is large) can be prevented, it is possible to sufficiently ensure the degree of freedom in the design of the wiring pattern.

As still another aspect, the present disclosure relates to a wiring-formed member. Such a wiring-formed member includes a base material including wiring, and a cured product of any of the wiring-forming members described above, which is disposed on the base material to cover the wiring. In such a wiring-formed member, the wiring, and the metal layer of the wiring-forming member or another wiring formed from the metal layer are electrically connected. According to such an aspect, as described above, since the insulating reliability in the portion of the wiring layer, in which conductive connection is not desired, can be ensured and/or the transmission loss of the wiring layer can be suppressed, or the occurrence of the air bubbles in a case where the substrate on which the wiring is to be formed by the wiring-forming member has large irregularities (for example, in a case where the height of the electrode is large) can be prevented, it is possible to sufficiently ensure the degree of freedom in the design of the wiring pattern.

### Advantageous Effects of Invention

According to the present disclosure, it is possible to simplify the process of forming the wiring layer connecting the wirings while sufficiently ensuring the degree of freedom in the design of the wiring pattern.

### BRIEF DESCRIPTION OF DRAWINGS

FIG. 1 is a cross-sectional view illustrating a wiring-forming member according to one embodiment of the present disclosure.

FIG. 2 is a cross-sectional view illustrating another example of the wiring-forming member according to one embodiment of the present disclosure.

FIGS. 3(a) to (d) in FIG. 3 are drawings for sequentially illustrating a wiring layer forming method using the wiring-forming member illustrated in FIG. 1.

FIGS. 4(a) and (b) in FIG. 4 are cross-sectional views for illustrating an example of a case where a wiring layer is formed using the wiring-forming member according to one embodiment of the present disclosure.

FIGS. 5(a) and (b) in FIG. 5 are cross-sectional views for illustrating an example of a case where the wiring layer is formed using a wiring-forming member according to Comparative Example.

FIGS. 6(a) and (b) in FIG. 6 are cross-sectional views for illustrating another example of a case where the wiring layer is formed using the wiring-forming member according to one embodiment of the present disclosure.

FIGS. 7(a) and (b) in FIG. 7 are cross-sectional views for illustrating another example of a case where the wiring layer is formed using the wiring-forming member according to Comparative Example.

FIGS. 8(a) to (c) in FIG. 8 are cross-sectional views for illustrating another example of a case where the wiring layer is formed using the wiring-forming member according to one embodiment of the present disclosure.

FIGS. 9(a) and (b) in FIG. 9 are cross-sectional views for illustrating an example of a case where the wiring layer is formed using wiring-forming member illustrated in FIG. 2.

FIGS. 10(a) to (d) in FIG. 10 are cross-sectional views for sequentially illustrating a method for producing a substrate with a built-in component of the related art.

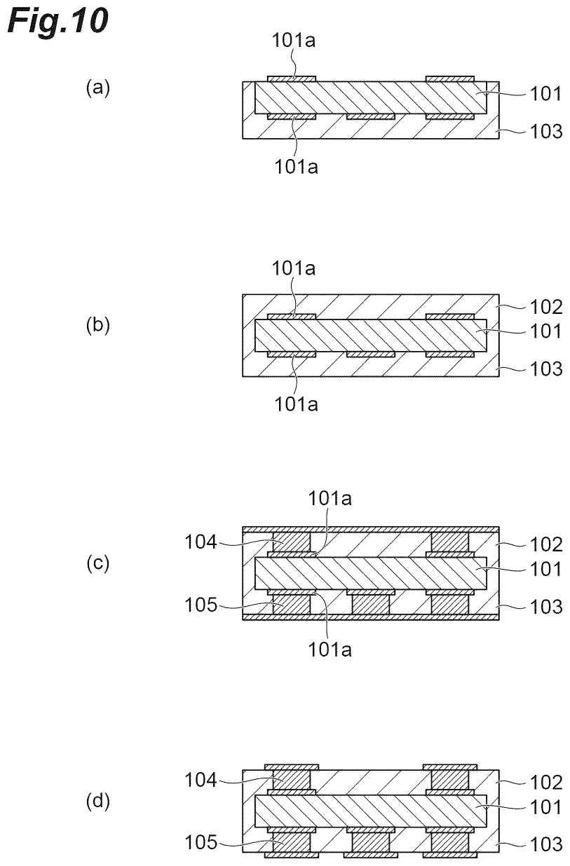

FIGS. 11(a) to (c) in FIG. 11 are cross-sectional views for sequentially illustrating the method for producing the substrate with a built-in component of the related art, which illustrate steps subsequent to FIG. 10.

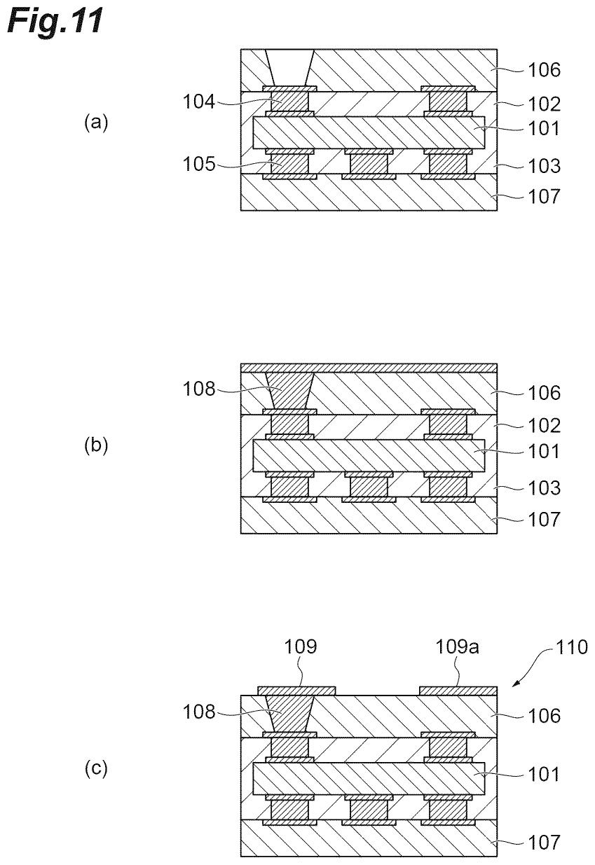

### DESCRIPTION OF EMBODIMENTS

Hereinafter, a wiring-forming member and a wiring layer forming method using the wiring-forming member according to one embodiment of the present disclosure will be described with reference to the drawings. Note that, in the present disclosure, wiring in wiring formation and wiring layer formation also includes a wiring pattern or the like including such as an electrode, a via, and a ground layer. In the following description, the same reference numerals will be applied to the same or corresponding parts, and the repeated description will be omitted. In addition, a positional relationship such as the top, bottom, right, and left is based on a positional relationship illustrated in the drawings, unless otherwise specified. Further, a dimensional ratio in the drawings is not limited to that illustrated.

In this specification, a numerical range represented by using “to” includes numerical values described before and after “to” as the minimum value and the maximum value, respectively. In addition, in numerical ranges described in stages in this specification, the upper limit value or the lower limit value described in one numerical range may be replaced with the upper limit value or the lower limit value of a numerical range described in the other stage. In addition, in the numerical range described in this specification, the upper limit value or the lower limit value of the numerical range may be replaced with values described in Examples.

A wiring-forming member of this embodiment includes an adhesive layer containing conductive particles, and a metal layer disposed on the adhesive layer. In the wiring-forming member, the adhesive layer may include a first adhesive layer containing the conductive particles and an adhesive component, and a second adhesive layer containing an adhesive component, or the adhesive layer, in the thickness direction thereof, may include a first region containing the conductive particles and a first adhesive component, and a second region containing a second adhesive component. The first region, for example, can be composed of the first adhesive layer, and the second region can be composed of the second adhesive layer.

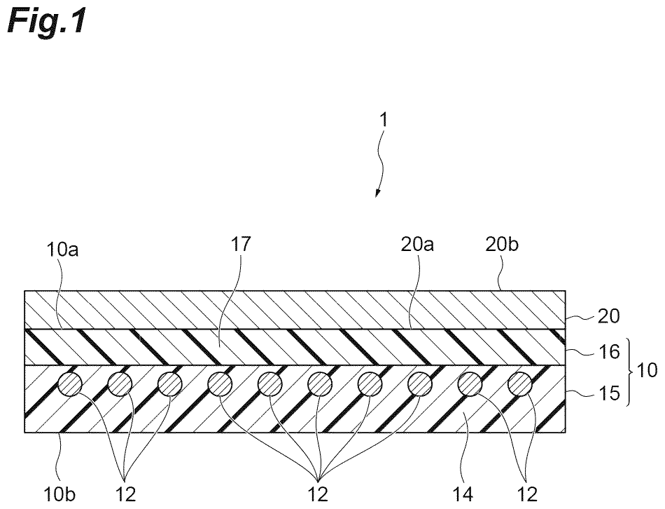

FIG. 1 is a cross-sectional view illustrating a wiring-forming member according to one embodiment of the present disclosure. As illustrated in FIG. 1, a wiring-forming member 1 is configured by including an adhesive layer 10 containing conductive particles 12, and a metal layer 20. The adhesive layer 10 includes a first adhesive layer 15 containing the conductive particles 12 and an adhesive component, and a second adhesive layer 16 containing an adhesive component. The wiring-forming member 1 has a configuration in which the metal layer 20, the second adhesive layer 16, and the first adhesive layer 15 are laminated in this order.

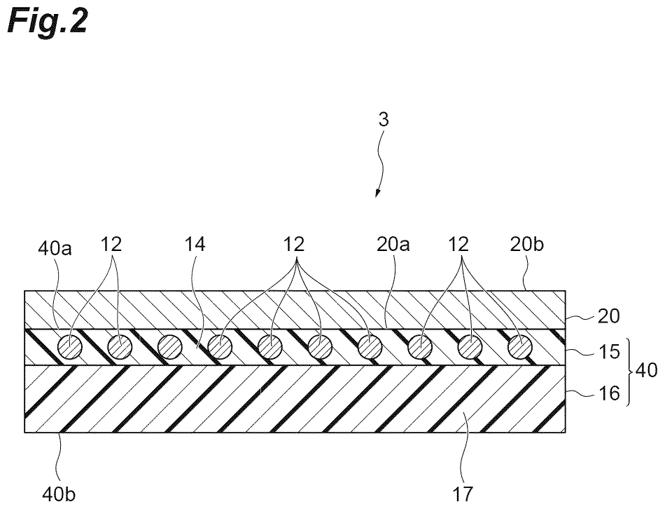

FIG. 2 is a cross-sectional view illustrating another example of the wiring-forming member according to one embodiment of the present disclosure. A wiring-forming member 3 illustrated in FIG. 2 is configured by including an adhesive layer 40 containing the conductive particles 12, and the metal layer 20, and the adhesive layer 40 includes the first adhesive layer 15 containing the conductive particles 12 and the adhesive component, and the second adhesive layer 16 containing the adhesive component. The wiring-forming member 3 has a configuration in which the metal layer 20, the first adhesive layer 15, and the second adhesive layer 16 are laminated in this order.

The wiring-forming members 1 and 3 are not limited thereto, and for example, are a member that can be used when producing a redistribution layer, a build-up multi-layer wiring board, a substrate with a built-in component, and the like. In addition, the wiring-forming members 1 and 3 may be used for an EMI shield or the like.

The first adhesive layer 15 is configured by containing the conductive particles 12, and an adhesive layer 14 containing an insulating adhesive component in which the conductive particles 12 are dispersed. The adhesive layer 14, for example, has a thickness of 1 to 50 μm. The adhesive component of the adhesive layer 14 is defined as a solid content other than the conductive particles 12. The adhesive layer 14 may be in a stage B state where the surface is dried, that is, a semi-cured state, before the wiring layer is formed by the wiring-forming member 1.

A thickness d1 of the first adhesive layer 15 may be 0.1 times or more, may be 0.2 times or more, may be 0.3 times or more, may be 0.5 times or more, may be 0.8 times or more, or may be 1 time or more an average particle diameter Dp of the conductive particles 12. The thickness d1 of the first adhesive layer 15 may be 10 times or less, may be 7 times or less, may be 5 times or less, may be 3 times or less, may be 2 times or less, or may be 1 time or less the average particle diameter Dp of the conductive particles 12.

The second adhesive layer 16 is configured by including an adhesive layer 17 containing an insulating adhesive component. The insulating adhesive component in the second adhesive layer 16 may be the same as or different from that of the first adhesive layer 14. The adhesive layer 17, for example, has a thickness of 1 to 50 μm. The adhesive component of the adhesive layer 17 is defined as a solid content other than the conductive particles. The adhesive layer 17 may be in a stage B state where the surface is dried, that is, a semi-cured state, before the wiring layer is formed by the wiring-forming member 1.

A thickness d2 of the second adhesive layer 16 may be 0.1 times or more, may be 0.5 times or more, may be 0.8 times or more, or may be 1 time or more the thickness d1 of the first adhesive layer 15. The thickness d2 of the second adhesive layer 16 may be 10 times or less, may be 7 times or less, may be 5 times or less, may be 3 times or less, or may be 1 time or less the thickness d1 of the first adhesive layer 15.

The wiring-forming member of this embodiment, as with the wiring-forming member 1, may be configured by sequentially laminating the metal layer, the second adhesive layer, and the first adhesive layer, or as with the wiring-forming member 3, may be configured by sequentially laminating the metal layer, the first adhesive layer, and the second adhesive layer. In addition, the first adhesive component contained in the first region may be the same as the insulating adhesive component in the adhesive layer 14, and the second adhesive component contained in the second region may be the same as the insulating adhesive component in the adhesive layer 17.

### [Configuration of Conductive Particles]

The conductive particles 12 are approximately spherical particles having conductivity, and are composed of metal particles consisting of a metal such as Au, Ag, Ni, Cu, and solder, conductive carbon particles consisting of conductive carbon, or the like. The conductive particles 12 may be coated conductive particles including a core containing non-conductive glass, ceramic, plastic (such as polystyrene), or the like, and a coating layer containing the metal described above or conductive carbon and covering the core. Among them, the conductive particles 12 may be metal particles formed of a hot-melt metal, or coated conductive particles including a core containing plastic, and a coating layer containing a metal or conductive carbon and covering the core.

In one embodiment, the conductive particles 12 include a core consisting of polymer particles (plastic particles) such as polystyrene, and a metal layer covering the core. In the polymer particles, substantially the entire surface may be coated with the metal layer, and a part of the surface of the polymer particles may be exposed without being coated with the metal layer within a range where a function as a connection material is maintained. The polymer particles, for example, may be particles containing a polymer having at least one type of monomer selected from styrene and divinyl benzene as a monomer unit.

The metal layer may be formed of various metals such as Ni, Ni/Au, Ni/Pd, Cu, NiB, Ag, and Ru. The metal layer may be an alloy layer consisting of an alloy of Ni and Au, an alloy of Ni and Pd, or the like. The metal layer may have a multi-layer structure consisting of a plurality of metal layers. For example, the metal layer may consist of a Ni layer and an Au layer. The metal layer may be produced by plating, vapor deposition, sputtering, solder, or the like. The metal layer may be a thin film (for example, a thin film formed by plating, vapor deposition, sputtering, or the like).

The conductive particles 12 may include an insulating layer. Specifically, for example, in the conductive particles of the embodiment described above, including the core (for example, the polymer particles), and the coating layer covering the core, such as the metal layer, the insulating layer further covering the coating layer may be provided outside the coating layer. The insulating layer may be an outermost surface layer positioned on the outermost surface of the conductive particles. The insulating layer may be a layer formed from an insulating material such as silica and an acrylic resin.

The average particle diameter Dp of the conductive particles 12, from the viewpoint of excellent dispersibility and conductivity, may be 1 μm or more, may be 2 μm or more, or may be 5 μm or more. The average particle diameter Dp of the conductive particles, from the viewpoint of excellent dispersibility and conductivity, may be 50 μm or less, may be 30 μm or less, or may be 20 μm or less. From the viewpoint described above, the average particle diameter Dp of the conductive particles may be 1 to 50 μm, may be 5 to 30 μm, may be 5 to 20 μm, or may be 2 to 20 μm.

The maximum particle diameter of the conductive particles 12 may be less than the minimum interval between the electrodes in the wiring pattern (the shortest distance between the adjacent electrodes). The maximum particle diameter of the conductive particles 12, from the viewpoint of excellent dispersibility and conductivity, may be 1 μm or more, may be 2 μm or more, or may be 5 μm or more. The maximum particle diameter of the conductive particles, from the viewpoint of excellent dispersibility and conductivity, may be 50 μm or less, may be 30 μm or less, or may be 20 μm or less. From the viewpoint described above, the maximum particle diameter of the conductive particles may be 1 to 50 μm, may be 2 to 30 μm, or may be 5 to 20 μm.

In this specification, for 300 pieces (pcs) of any particles, a particle diameter is measured by observation using a scanning electron microscope (SEM), the average value of the particle diameters obtained is set to the average particle diameter Dp, and the largest value obtained is set to the maximum particle diameter of the particles. Note that, in a case where the particles are not in a spherical shape, such as a case where the particles have a protrusion, the particle diameter of the particles is set to the diameter of a circle circumscribed around the particle in the image of SEM.

The content of the conductive particles 12 is determined in accordance with the definition of the electrode to be connected, or the like. For example, the blending amount of the conductive particles 12 is not particularly limited, but may be 0.1% by volume or more, or may be 0.2% by volume or more, on the basis of the total volume of the adhesive component (a component excluding the conductive particles in an adhesive composition). In a case where the blending amount is 0.1% by volume or more, there is a tendency that a decrease in the conductivity is suppressed. The blending amount of the conductive particles 12 may be 30% by volume or less, or may be 10% by volume or less, on the basis of the total volume of the adhesive component (the component excluding the conductive particles 12 in the adhesive composition). In a case where the blending amount is 30% by volume or less, there is a tendency that the short circuit of a circuit is less likely to occur. Note that, “% by volume” is determined on the basis of the volume of each component before curing at 23° C., but the volume of each component can be converted from weight to volume using specific weight. In addition, the component is put in a graduated cylinder or the like in which a suitable solvent (water, alcohol, or the like) for wetting the component without dissolving or swelling the component is put, and the increased volume can also be obtained as the volume of the component.

### [Configuration of Adhesive Layer/Adhesive Component]

The adhesive component configuring the adhesive layers 14 and 17 contains a curing agent and a monomer. In the case of using an epoxy resin monomer, as the curing agent, an imidazole-based curing agent, a hydrazide-based curing agent, a boron trifluoride-amine complex, a sulfonium salt, amine imide, a polyamine salt, dicyandiamide, or the like can be used. It is preferable to micro-encapsulate the curing agent by coating the curing agent with a polyurethane-based polymer substance, a polyester-based polymer substance, or the like, since a usable time is extended. On the other hand, in the case of using an acrylic monomer, as the curing agent, a peroxide compound, an azo-based compound, or the like, which is decomposed by heating to generate free radicals, can be used.

The curing agent in the case of using the epoxy monomer is suitably selected in accordance with the intended connection temperature, connection time, storage stability, and the like. In the curing agent, from the viewpoint of high reactivity, a gelling time with an epoxy resin composition may be within 10 seconds at a predetermined temperature, and from the viewpoint of storage stability, the gelling time with the epoxy resin composition may not be changed after storage in a constant-temperature bath at 40° C. for 10 days. From such a viewpoint, the curing agent may be a sulfonium salt.

The curing agent in the case of using the acrylic monomer is suitably selected in accordance with the intended connection temperature, connection time, storage stability, and the like. From the viewpoint of high reactivity and storage stability, the curing agent may be an organic peroxide or an azo-based compound in which a temperature for the half-life of 10 hours is 40° C. or higher and a temperature for the half-life of 1 minute is 180° C. or lower, or may be an organic peroxide or an azo-based compound in which a temperature for the half-life of 10 hours is 60° C. or higher and a temperature for the half-life of 1 minute is 170° C. or lower. Such curing agents can be used alone or by being mixed, and may be used by being mixed with a decomposition accelerator, an inhibitor, or the like.

In a case where the connection time is 10 seconds or shorter when using either the epoxy monomer or the acrylic monomer, in order to obtain a sufficient reaction rate, the blending amount of the curing agent may be 0.1 parts by mass to 40 parts by mass, or may be 1 part by mass to 35 parts by mass, with respect to a total of 100 parts by mass of the following monomer and the following film forming material. In a case where the blending amount of the curing agent is less than 0.1 parts by mass, it is not possible to obtain a sufficient reaction rate, and there is a tendency that excellent adhesive strength or small connection resistance is less likely to be obtained. On the other hand, in a case where the blending amount of the curing agent is greater than 40 parts by mass, there is a tendency that the fluidity of the adhesive decreases, the connection resistance increases, or the storage stability of the adhesive decreases.

In addition, in the case of using the epoxy resin monomer, as the monomer, a bisphenol-type epoxy resin derived from epichlorohydrin and bisphenol A, bisphenol F, bisphenol AD, or the like, an epoxy novolac resin derived from epichlorohydrin and phenol novolac or cresol novolac, various epoxy compounds having two or more glycidyl groups in one molecule, such as glycidyl amine, glycidyl ether, biphenyl, and an alicyclic compound, and the like can be used.

In the case of using the acrylic monomer, a radical polymerizable compound may be a substance having a functional group polymerized by radicals. Examples of such a radical polymerizable compound include (meth)acrylate, a maleimide compound, and a styrene derivative. In addition, the radical polymerizable compound can be used in either a monomer state or an oligomer state, and may be used by mixing the monomer and the oligomer. Only one type of such monomers may be used alone, or two or more types thereof may be used by being mixed.

In addition, the adhesive layer forming the adhesive layers 14 and 17 may further contain a film forming material, a filler, a softener, an accelerator, an age inhibitor, a colorant, a flame retardant, a thixotropic agent, a coupling agent, a phenol resin or a melamine resin, isocyanates, and the like.

In a case where the adhesive layer contains the film forming material, an improvement in film formability can be expected. The film forming material is a polymer having a function of facilitating the handling of a low-viscosity composition containing the curing agent and the monomer. By using the film forming material, the film is prevented from being easily torn, cracked, or sticky, and the easy-to-handle adhesive layers 14 and 17 are obtained.

As the film forming material, a thermoplastic resin is preferably used, and examples thereof include a phenoxy resin, a polyvinyl formal resin, a polystyrene resin, a polyvinyl butyral resin, a polyester resin, a polyamide resin, a xylene resin, a polyurethane resin, a polyacrylic resin, and a polyester urethane resin. Further, in such polymers, a siloxane bond or a fluorine substituent may be contained. Only one type of such resins can be used alone, or two or more types thereof can be used by being mixed. Among the resins described above, the phenoxy resin may be used from the viewpoint of adhesive strength, compatibility, heat resistance, and mechanical strength.

As the molecular weight of the thermoplastic resin increases, the film formability is easily obtained, and a melt viscosity affecting the fluidity of the film can be set in a wide range. As the molecular weight of the thermoplastic resin, a weight average molecular weight may be 5000 to 150000, or may be 10000 to 80000. By setting the weight average molecular weight to 5000 or more, excellent film formability is easily obtained, and by setting the weight average molecular weight to 150000 or less, excellent compatibility with other components is easily obtained.

Note that, in the present disclosure, the weight average molecular weight indicates a value measured using a calibration curve of standard polystyrene obtained by gel permeation chromatography (GPC), in accordance with the following condition.

### (Measurement Condition)

Device: manufactured by Tosoh Corporation, GPC-8020
Detector: manufactured by Tosoh Corporation, R1-8020
Column: manufactured by Hitachi Chemical Company, Ltd., Gelpack GLA160S+GLA150S
Sample concentration: 120 mg/3 mL
Solvent: tetrahydrofuran
Injection amount: 60 μL
Pressure: 2.94×106 Pa (30 kgf/cm²)
Flow rate: 1.00 mL/min

In a case where the adhesive layer contains the film forming material, the content of the film forming material may be 5% by mass to 80% by mass, or may be 15% by mass to 70% by mass, on the basis of the total amount of the curing agent, the monomer, and the film forming material. By setting the content to 5% by mass or more, excellent film formability is easily obtained, and by setting the content to 80% by mass or less, there is a tendency that the curable composition exhibits excellent fluidity.

In the case of containing the filler, an improvement in connection reliability can be further expected. The maximum diameter of the filler may be less than the particle diameter of the conductive particles 12, and the content of the filler may be 5 parts by volume to 60 parts by volume with respect to 100 parts by volume of the adhesive layer. In a case where the content of the filler is 5 parts by volume to 60 parts by volume, there is a tendency that excellent connection reliability is obtained.

### [Configuration of Metal Layer]

One surface and the opposite surface of the metal layer 20 may have the same surface roughness Rz, or may have different surface roughness Rz. The metal layer 20, for example, has a thickness of 5 to 200 μm. Here, the thickness of the metal layer is a thickness including the surface roughness Rz. The metal layer 20, for example, is a copper foil, an aluminum foil, a nickel foil, stainless steel, titanium, or platinum. The metal layer 20 may be a layer of a metal foil.

The adhesive layer 10 is disposed on a first surface 20a of the metal layer 20. From the viewpoint of adhesiveness between the metal layer 20 and the adhesive layer 10 or the adhesive layer 40, the surface roughness Rz of the first surface 20a of the metal layer 20 (the surface on a side adhering to the adhesive layer 10 or the adhesive layer 40) may be 0.3 μm or more, may be 0.5 μm or more, or may be 1.0 μm or more. In addition, from the viewpoint of attaining excellent electrical conduction, the surface roughness Rz of the first surface 20a of the metal layer 20 may be 50 μm or less, may be 40 μm or less, may be 30 μm or less, may be 20 μm or less, may be less than 20 μm, may be 17 μm or less, may be 10 μm or less, may be 8.0 μm or less, may be 5.0 μm or less, or may be 3.0 μm or less. The surface roughness Rz of the first surface 20a of the metal layer 20, for example, may be 0.3 μm or more and 20 μm or less, or may be 0.3 μm or more and less than 20 μm, and more specifically, may be 0.5 μm or more and 10 μm or less. Note that, the surface roughness Rz of a second surface 20b of the metal layer 20, for example, may be 20 μm or more, may be coarser than the surface roughness Rz of the first surface 20a, may be the same as the surface roughness of the first surface 20a, or may not be coarser than the surface roughness Rz of the first surface 20a.

The surface roughness Rz indicates ten-point average roughness Rzjis measured on the basis of a method defined in JIS Standard (JIS B 0601-2001), and indicates a value measured using a commercially available surface roughness/contour measuring machine. For example, the surface roughness can be measured using a nano-search microscope (manufactured by SHIMADZU CORPORATION, “SFT-3500”).

Here, a relationship between the average particle diameter Dp of the conductive particles 12 and the surface roughness Rz of the first surface 20a of the metal layer 20 will be described below. In this embodiment, “surface roughness/average particle diameter” that is a ratio of the surface roughness Rz of the first surface 20a of the metal layer 20 to the average particle diameter Dp of the conductive particles 12 may be 0.03 or more, may be 0.04 or more, may be 0.05 or more, may be 0.06 or more, may be 0.1 or more, may be 0.2 or more, may be 0.3 or more, may be 0.5 or more, or may be 1 or more. In addition, “surface roughness/average particle diameter” that is the ratio of the surface roughness Rz of the first surface 20a of the metal layer 20 to the average particle diameter Dp of the conductive particles 12 may be 3 or less, may be 2 or less, may be 1.7 or less, or may be 1.5 or less. “Surface roughness/average particle diameter” that is the ratio of the surface roughness Rz of the first surface 20a of the metal layer 20 to the average particle diameter Dp of the conductive particles 12, for example, may be 0.05 or more and 3 or less, and more specifically, may be 0.06 or more and 2 or less.

From the viewpoint of preventing the occurrence of air bubbles in a case where the substrate on which wiring is to be formed has large irregularities (for example, the height of the electrode is large), in the wiring-forming member 3, the fluidity of the second adhesive layer 16 (or the second region) may be higher than the fluidity of the first adhesive layer 15 (or the first region). In the fluidity of the adhesive layer, for example, a flow rate can be an index.

In the wiring-forming member 3, a ratio of the flow rate of the second adhesive layer 16 to the flow rate of the first adhesive layer 15 (hereinafter, referred to as a “flow ratio”) may be greater than 1.0, may be greater than 1.0 and 3.0 or less, or may be greater than 1.0 and 2.0 or less. Note that, in a case where the adhesive layer, in the thickness direction thereof, includes the first region containing the conductive particles and the first adhesive component, and the second region containing the second adhesive component, and the metal layer, the first region, and the second region are provided adjacent to each other in this order, a ratio of the flow rate of the second region to the flow rate of the first region (hereinafter, referred to as a “flow ratio”) may be greater than 1.0, may be greater than 1.0 and 3.0 or less, or may be greater than 1.0 and 2.0 or less.

The flow rate of each of the adhesive layers (the first adhesive layer and the second adhesive layer) is a flow rate when placing the adhesive layer on a glass plate from the first adhesive layer side, performing temporary compression bonding in the condition of a compression bonding temperature of 70° C., a compression bonding pressure of 0.1 MPa, and a compression bonding time of 1.0 s, and then, placing the glass plate on the second adhesive layer, and performing main compression bonding in the condition of a compression bonding temperature of 180° C., a compression bonding pressure of 2 MPa, and a compression bonding time of 10 minutes, and is defined by Formula (1) described below.

$$Flow Rate [ \% ] = {S}_{B} / {S}_{A} \times 100 \qquad ( 1 )$$

In Formula (1), SA indicates the surface area of the adhesive layer before the temporary compression bonding, and SB indicates the area of the adhesive layer after the main compression bonding.

Specifically, the flow rate of each of the adhesive layers described above can be measured in the following procedures of (I) to (IV).
(I) The wiring-forming member is punched out in the thickness direction in the state of including the metal layer to obtain a discoid adhesive film for evaluation with a radius r.
(II) The adhesive film for evaluation is placed on a first glass plate from the second adhesive layer side, and thermocompression bonding is performed from the metal layer side in the condition of a compression bonding temperature of 70° C., a compression bonding pressure of 0.1 MPa, and a compression bonding time of 1.0 s to obtain a temporarily fixed body.
(III) A second glass plate is placed on the metal layer of the temporarily fixed body, thermocompression bonding is performed from the metal layer side in the condition of a compression bonding temperature of 180° C., a compression bonding pressure of 2 MPa, and a compression bonding time of 10 minutes to obtain a compression-bonded body.
(IV) In the compression-bonded body, a contact area S_{B1} (unit: mm²) between the metal layer and the first adhesive layer and the first glass plate protruding from the metal layer, and an adhesion area S_{B2} (unit: mm²) between the surface on the second adhesive layer side and the second glass plate are obtained, and the flow rate of the first adhesive layer and the flow rate of the second adhesive layer are calculated on the basis of Formula (1-1) and Formula (1-2) described below.

$$Flow Rate [ \% ] of First Adhesive Layer = {S}_{B 1} / ( {r}^{2} π ) \times 100 \qquad ( 1 - 1 )$$

$$Flow Rate [ \% ] of Second Adhesive Layer = {S}_{B 2} / ( {r}^{2} π ) \times 100 \qquad ( 1 - 2 )$$

Examples of means for increasing the fluidity of the adhesive layer include the adjustment of the configuration of the adhesive component, and the adjustment of the content of the filler.

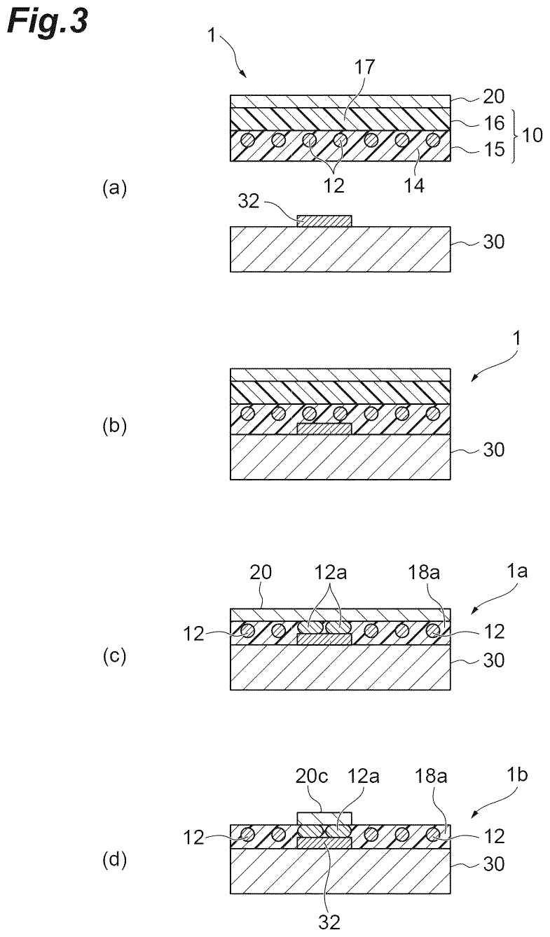

As another aspect, the present disclosure relates to a method for forming the wiring layer using the wiring-forming member. The method for forming the wiring layer using the wiring-forming member 1 will be described with reference to FIG. 2. (a) to (d) in FIG. 3 are drawings illustrating a wiring layer forming method using the wiring-forming member illustrated in FIG. 1.

First, as illustrated in (a) in FIG. 3, the wiring-forming member 1 is prepared. Further, a base material 30 on which a wiring 32 is formed is prepared. Then, the wiring-forming member 1 is disposed such that the adhesive layer 10 side of the wiring-forming member 1 faces the base material 30. After that, as illustrated in (b) in FIG. 3, lamination is performed to cover the wiring 32, and the wiring-forming member 1 is attached to the base material 30.

Subsequently, as illustrated in (c) in FIG. 3, predetermined heating and pressurizing are performed on the wiring-forming member 1, and compression bonding with respect to the base material 30 is performed. In this case, in a case where the first surface 20a of the metal layer 20 of the wiring-forming member 1 is flat, it is possible to more reliably deform the conductive particles 12 required to ensure conductivity to the conductive particles 12a in a flattened shape. Then, in the compression-bonded wiring-forming member 1a, the flattened conductive particles 12a (accordingly, the insulating layer is damaged and a conduction part is exposed) is disposed on the wiring 32, and excellent electrical conduction between the metal layer 20 and the wiring 32 is attained. In this case, the adhesive layer 10 is also pressed to be a thinner adhesive layer 18a. In addition, since the adhesive layer 10 includes the first adhesive layer 15 in which the conductive particles are contained in the adhesive component, and the second adhesive layer 16, excellent insulating reliability in a portion in the thickness direction, in which conductive connection is not desired, is attained.

Subsequently, as illustrated in (d) in FIG. 3, a predetermined patterning treatment (for example, an etching treatment) is performed on the metal layer 20 such that the metal layer is processed to a predetermined wiring pattern 20c (another wiring). Note that, in this case, a treatment of making the surface smooth may be implemented on the second surface 20b of the metal layer 20. The treatment of (a) to (d) in FIG. 3 described above may be repeated a predetermined number of times to form the wiring layer.

That is, the wiring layer forming method using the wiring-forming member includes a step of preparing the wiring-forming member, a step of preparing the base material on which the wiring is formed, a step of disposing the wiring-forming member on the surface of the base material on which the wiring is formed such that the adhesive layer side faces the substrate to cover the wiring, a step of thermocompression-bonding the wiring-forming member to the base material, and a step of performing the patterning treatment on the metal layer.

As described above, a wiring-formed member 1b is formed. Such a wiring-formed member 1b includes the base material 30 including the wiring 32, a cured product of the wiring-forming member 1 (the thermocompression-bonded wiring-forming member) disposed on the base material 30 to cover the wiring 32. In such a wiring-formed member 1b, the wiring 32, and the metal layer 20 of the wiring-forming member 1 or the wiring pattern 20c formed (for example, etching-processed) from the metal layer 20 are electrically connected by the conductive particles 12a. Note that, in a case where the treatment of (a) to (d) in FIG. 3 is repeated a predetermined number of times, the wiring-formed member 1b may have a configuration including a plurality of wiring layers (layers connecting the wirings described above).

As described above, according to the wiring layer forming method using the wiring-forming member 1 according to this embodiment, a process of forming the wiring layer connecting the wirings can be simplified compared to the process of the related art in which laser processing, a filled plating treatment, and the like are performed. In addition, it is possible to easily make the formed wiring layer thin. For the case of using the wiring-forming member 3, the same effect can also be obtained by performing the same steps described above.

Further, according to the wiring layer forming method using the wiring-forming member 1 according to this embodiment, by the following effects, it is possible to sufficiently ensure the degree of freedom in the design of the wiring pattern when forming the wiring layer.
(i) By the adhesive layer 10 including the second adhesive layer 16, even in a case where the wiring layer formed by patterning the metal layer 20 includes the portion in the lamination direction (or the thickness direction of the adhesive layer), in which conductive connection is not desired, it is easy to ensure the insulating reliability in the portion.
(ii) In the wiring layer formed by patterning the metal layer 20 or redistribution separately formed, the conductive particles 12 are less likely to be in contact with a portion other than a portion conductively connected, and a transmission loss of the wiring due to the contact of the conductive particles is likely to be suppressed.

The effects described above will be described with reference to the drawings.

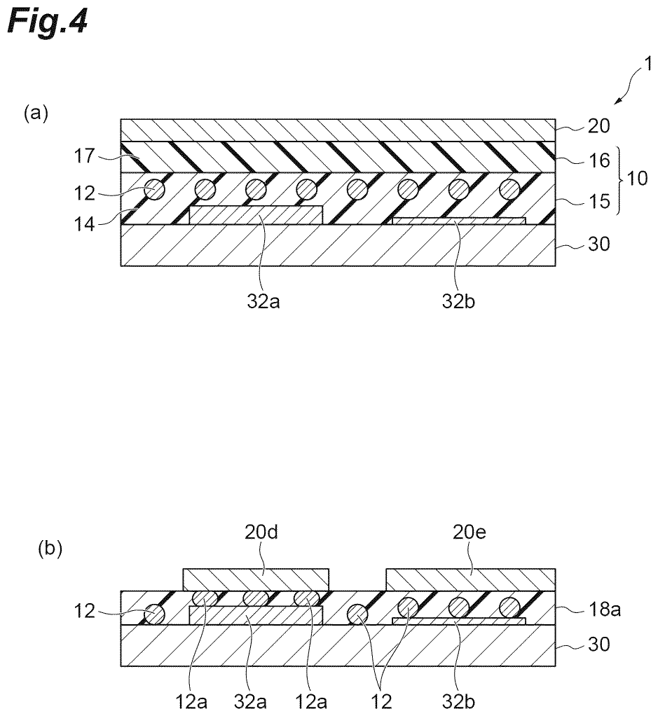

(a) and (b) in FIG. 4 are cross-sectional views for illustrating an example of a case where the wiring layer is formed using the wiring-forming member 1 according to this embodiment.

(a) in FIG. 4 illustrates a state when the base material 30 including a wiring pattern 32a and a wiring pattern 32b is prepared, and the wiring-forming member 1 is disposed on the surface of the base material 30 on which the wiring pattern is formed such that the adhesive layer 10 side faces the base material 30 to cover the wiring patterns 32a and 32b. After that, as illustrated in (b) in FIG. 4, the wiring-formed member in which the wiring pattern 20d conductively connected to the wiring pattern 32a, and a wiring pattern 20e not desired to be conductively connected to the wiring pattern 32b are formed is obtained through the step of thermocompression-bonding the wiring-forming member 1 to the base material 30 and the step of performing the patterning treatment on the metal layer 20.

Here, by the adhesive layer 10 of the wiring-forming member 1 including the first adhesive layer 15 containing the conductive particles 12 and the adhesive component 14, and the second adhesive layer 16 containing the adhesive component 17 without containing the conductive particles, it is possible to provide the adhesive layer 18a with a thickness capable of ensuring a distance in which the conduction by the conductive particles 12 does not occur between the wiring pattern 20e, in which conductive connection is not desired, and the wiring pattern 32b while ensuring excellent conduction between the wirings of the wiring pattern 20d and the wiring pattern 32a through the conductive particles 12 during compression bonding. Accordingly, the wiring pattern 20e and the wiring pattern 32b are not conductively connected, and it is possible to ensure the insulating reliability in the thickness direction of the adhesive layer.

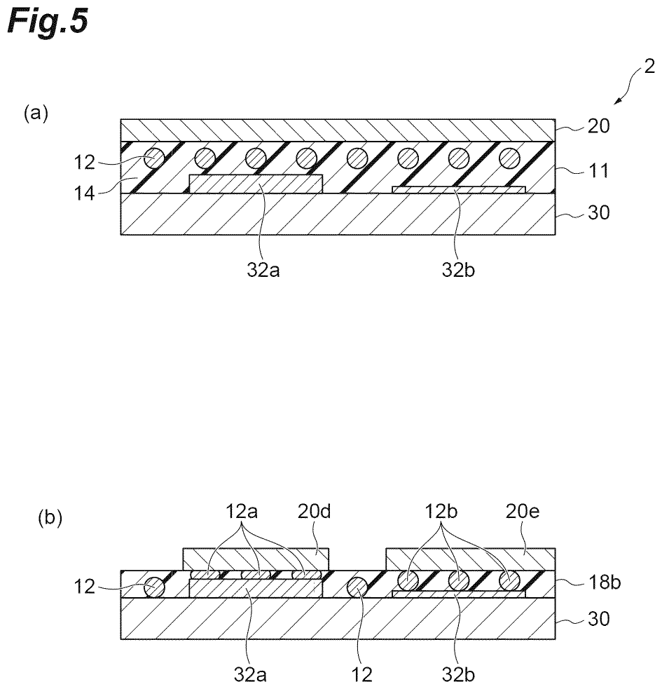

On the other hand, (a) and (b) in FIG. 5 are cross-sectional views for illustrating an example of a case where the wiring layer is formed using a wiring-forming member 2, which is Comparative Example. In the wiring-forming member 2, an adhesive layer 11 is composed of only a single layer containing the conductive particles 12 and the adhesive component 14. In this case, as described above, in a case where the disposition of the wiring-forming member 2, the thermocompression bonding, and the patterning treatment are performed, excellent conduction can be ensured between the wirings of the wiring pattern 20d and the wiring pattern 32a through the conductive particles 12, but conduction is attained even between the wiring pattern 20e, in which conductive connection is not desired, and the wiring pattern 32b by the conductive particles 12b. That is, it is difficult to provide the adhesive layer 18b with the thickness capable of ensuring the distance in which the conduction by the conductive particles 12 does not occur between the wiring pattern 20e, in which conductive connection is not desired, and the wiring pattern 32b while ensuring excellent conduction between the wirings of the wiring pattern 20d and the wiring pattern 32a through the conductive particles 12. Therefore, the degree of freedom in the design of the wiring pattern when forming the wiring layer is restricted.

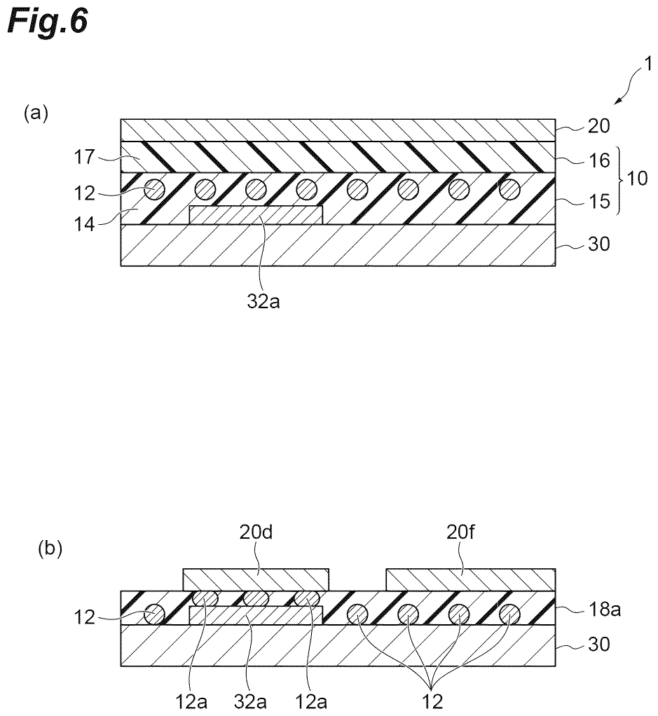

(a) and (b) in FIG. 6 are cross-sectional views for illustrating another example of a case where the wiring layer is formed using the wiring-forming member 1 according to this embodiment.

(a) in FIG. 6 illustrates a state when the base material 30 including the wiring pattern 32a is prepared, and the wiring-forming member 1 is disposed on the surface of the base material 30 on which the wiring pattern is formed such that the adhesive layer 10 side faces the base material 30 to cover the wiring pattern 32a. After that, as illustrated in (b) in FIG. 5, the wiring-formed member in which the wiring pattern 20d conductively connected to the wiring pattern 32a, and a wiring pattern 20f not conductively connected (or a portion in the wiring pattern, which is not conductively connected) are formed is obtained through the step of thermocompression-bonding the wiring-forming member 1 to the base material 30 and the step of performing the patterning treatment on the metal layer 20.

Here, by the adhesive layer 10 of the wiring-forming member 1 including the first adhesive layer 15 containing the conductive particles 12 and the adhesive component 14, and the second adhesive layer 16 containing the adhesive component 17 without containing the conductive particles, it is possible to provide the adhesive layer 18a for preventing the contact between the wiring pattern 20f and the conductive particles 12 while ensuring excellent conduction between the wirings of the wiring pattern 20d and the wiring pattern 32a through the conductive particles 12 during compression bonding. Accordingly, in the wiring pattern 20f, it is possible to suppress the transmission loss of the wiring due to the contact of the conductive particles. In particular, in the wiring-forming member 1, by laminating the metal layer 20, the second adhesive layer 16, and the first adhesive layer 15 in this order, it is easy to prevent the contact between the wiring pattern 20f and the conductive particles 12.

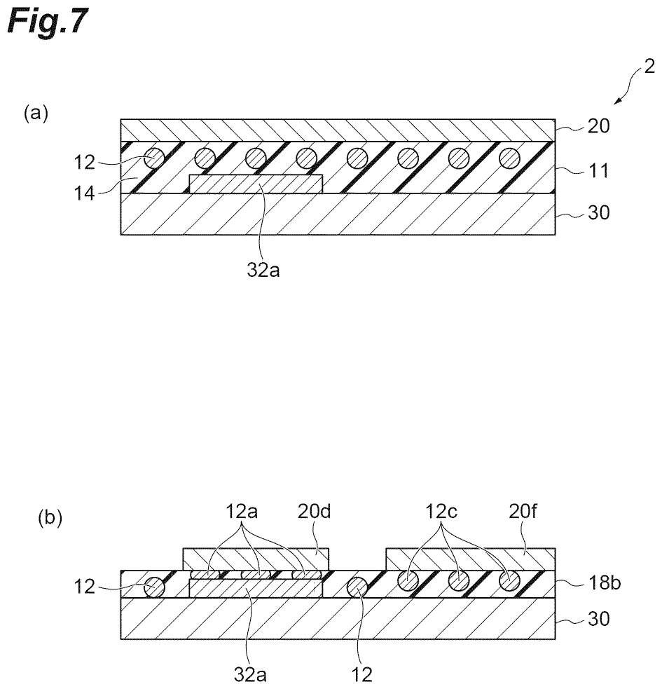

On the other hand, (a) and (b) in FIG. 7 are cross-sectional views for illustrating an example of a case where the wiring layer is formed using the wiring-forming member 2, which is Comparative Example. In the wiring-forming member 2, the adhesive layer 11 is composed of only a single layer containing the conductive particles 12 and the adhesive component 14. In this case, as described above, in a case where the disposition of the wiring-forming member 2, the thermocompression bonding, and the patterning treatment are performed, excellent conduction can be ensured between the wirings of the wiring pattern 20d and the wiring pattern 32a through the conductive particles 12, but the conductive particles 12c are in contact with the wiring pattern f (or the portion in the wiring pattern, which is not conductively connected). In a case where the conductive particles 12c increase, the transmission loss of the wiring also increases. Therefore, the degree of freedom in the design of the wiring pattern when forming the wiring layer is restricted.

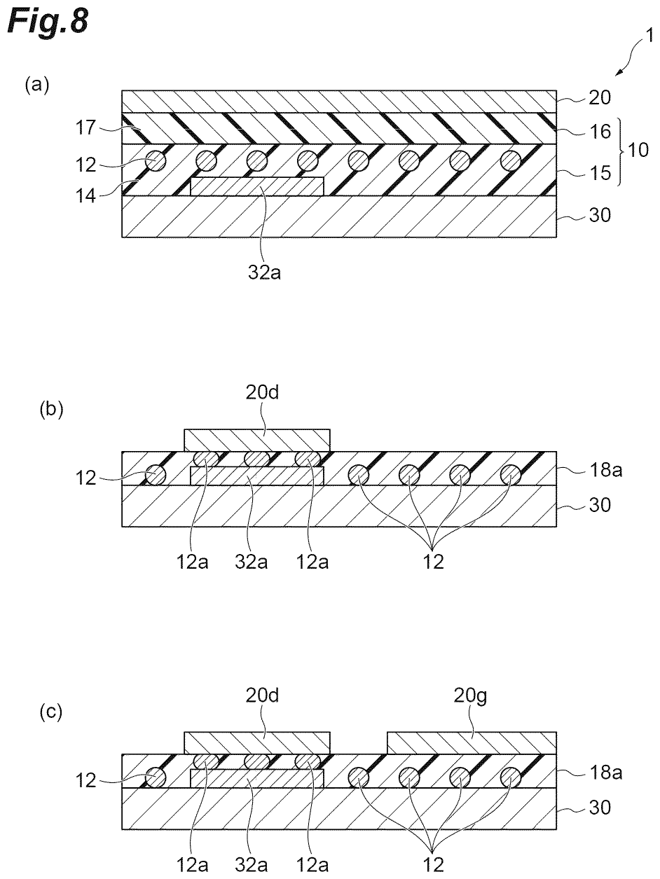

(a) to (c) in FIG. 8 are cross-sectional views for illustrating another example of a case where the wiring layer is formed using the wiring-forming member 1 according to this embodiment.

(a) in FIG. 8 illustrates a state where the base material 30 including the wiring pattern 32a is prepared, and the wiring-forming member 1 is disposed on the surface of the base material 30 on which the wiring pattern is formed such that the adhesive layer 10 side faces the base material 30 to cover the wiring pattern 32a. After that, as illustrated in (b) in FIG. 8, the wiring pattern 20d conductively connected to the wiring pattern 32a is formed through the step of thermocompression-bonding the wiring-forming member 1 to the base material 30 and the step of performing the patterning treatment on the metal layer 20. Further, as illustrated in (c) in FIG. 8, the wiring-formed member in which a redistribution pattern 20g not conductively connected (or a portion in the redistribution pattern, which is not conductively connected) is formed is obtained through a step of forming the redistribution.

Even in such a case, as with the wiring-formed member illustrated in (b) in FIG. 6, in the redistribution pattern 20g, it is possible to suppress the transmission loss of the wiring due to the contact of the conductive particles.

In addition, according to the wiring layer forming method using the wiring-forming member 3 according to this embodiment, by the following effects, it is possible to sufficiently ensure the degree of freedom in the design of the wiring pattern when forming the wiring layer.

(i) By the adhesive layer 40 including the second adhesive layer 16, even in a case where the substrate on which the wiring is to be formed by the wiring-forming member has large irregularities (for example, in a case where the height of the electrode is large), it is possible to ensure embeddability by the second adhesive layer or the second region, and prevent the occurrence of air bubbles or peeling.

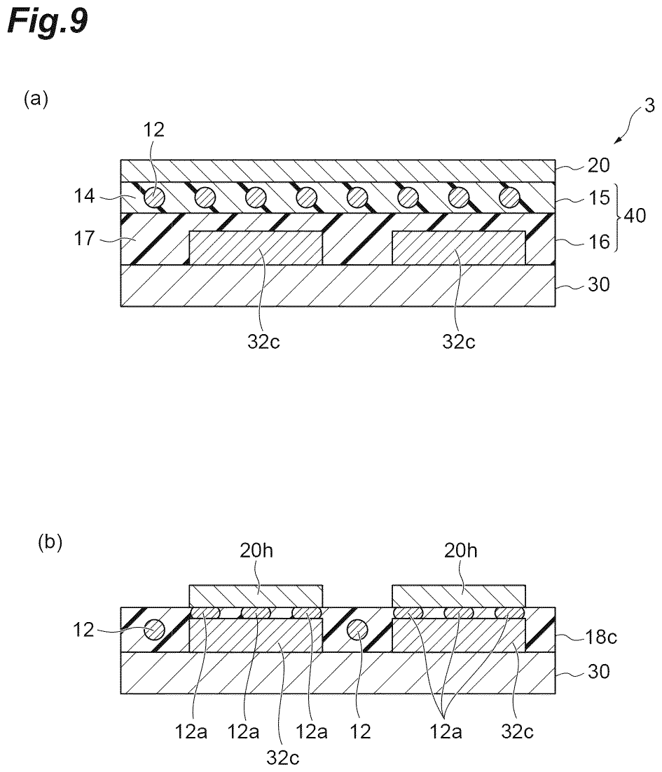

(a) and (b) in FIG. 9 are cross-sectional views for illustrating an example of a case where the wiring layer is formed using the wiring-forming member 3 according to this embodiment.

(a) in FIG. 9 illustrates a state where the base material 30 including an electrode 32c is prepared, and the wiring-forming member 3 is disposed on the surface of the base material 30 on which the wiring pattern is formed such that the adhesive layer 40 side faces the base material 30 to cover the electrode 32c. After that, as illustrated in (b) in FIG. 9, a wiring pattern 20h conductively connected to the electrode 32c is formed through the step of thermocompression-bonding the wiring-forming member 3 to the base material 30 and the step of performing the patterning treatment on the metal layer 20.

Here, by the adhesive layer 40 of the wiring-forming member 3 including the first adhesive layer 15 containing the conductive particles 12 and the adhesive component 14, and the second adhesive layer 16 containing the adhesive component 17 without containing the conductive particles, it is possible to ensure excellent conduction between the wiring pattern 20h and the electrode 32c through the conductive particles 12 during compression bonding. In addition, as described above, by setting the fluidity of the second adhesive layer to be higher than the fluidity of the first adhesive layer, even in a case where the height of the electrode 32c is set to be large, and the surface of the base material 30 has large irregularities, the air bubbles or the peeling are less likely to occur around the electrode 32c.

As described above, the embodiment of the present disclosure has been described in detail, but the present disclosure is not limited to the embodiment described above, and can be applied to various embodiments.

For example, as illustrated in FIG. 1, in the first adhesive layer 15 of the wiring-forming member 1, the conductive particles 12 are locally disposed, but the conductive particles 12 may be dispersed in the adhesive layer 14 randomly or on average.

In addition, in the first adhesive layer 15 of the wiring-forming member 1, the conductive particles 12 are locally disposed on the second adhesive layer 16 side, but the conductive particles 12 may be locally disposed on a side opposite to the second adhesive layer 16 side (a second surface 10b side of the adhesive layer 10).

Further, as with the wiring-forming member 3, in the case of having a configuration in which the metal layer 20, the first adhesive layer 15, and the second adhesive layer 16 are sequentially laminated, the conductive particles 12 may be locally disposed on the metal layer 20 side, or the conductive particles 12 may be locally disposed on the second adhesive layer 16 side.

In addition, the conductive particles are not contained in the second adhesive layer 16 of the wiring-forming members 1 and 3, but the second adhesive layer 16 may contain a part of the particle bodies of the conductive particles 12 (in other words, may not contain all of the particle bodies of the conductive particles 12).

In addition, the adhesive layer 10 of the wiring-forming member 1 or the adhesive layer 40 of the wiring-forming member 3 may be composed of two layers of the first adhesive layer 15 and the second adhesive layer 16, or may be composed of three or more layers including layers (for example, a third adhesive layer) in addition to the first adhesive layer 15 and the second adhesive layer 16. The third adhesive layer may be a layer having the same composition as the composition described above for the first adhesive layer 15 or the second adhesive layer 16, or may be a layer having the same thickness as the thickness described above for the first adhesive layer 15 or the second adhesive layer 16. For example, the wiring-forming member 3 may be configured by sequentially laminating the metal layer, the third adhesive layer, the first adhesive layer, and the second adhesive layer, and the wiring-forming member 1 may be configured by sequentially laminating the metal layer, the second adhesive layer, the first adhesive layer, and the third adhesive layer, but are not limited thereto.

In addition, the wiring-forming members 1 and 3 may further include a peeling film. The peeling film may adhere to the surface of the adhesive layer 10 or the adhesive layer 40 on a side opposite to the surface to which the metal layer 20 adheres (the second surface 10b side of the adhesive layer 10 or a second surface 40b side of the adhesive layer 40), or may adhere to the surface of the metal layer 20 (the second surface 20b side of the metal layer 20) on a side opposite to the surface to which the adhesive layer 10 or the adhesive layer 40 adheres (the first surface 20a of the metal layer). In this case, it is easy to handle the wiring-forming member, and it is possible to improve an operation efficiency when forming the wiring layer using the wiring-forming member.

In addition, in the above description, a case where the wiring-forming member is a member obtained by the adhesive layer 10 or the adhesive layer 40 adhering to the metal layer 20 has been described as an example, but in the wiring-forming member in this embodiment, the adhesive layer 10 or the adhesive layer 40 and the metal layer 20 may be separately provided, or may be configured as a combined product in which the adhesive layer 10 is adherable to the first surface 20a of the metal layer 20 at the time of use. In this case, since the adhesive layer 10 or the adhesive layer 40 and the metal layer 20 can be separately (as a set for the wiring-forming member) prepared, it is possible to improve the degree of freedom in the operation when producing the wiring layer using the wiring-forming member, such as selecting a wiring-forming member with a more optimum material configuration.

The present disclosure is capable of providing the inventions according to [1] to described below.
[1] A wiring-forming member, including: an adhesive layer containing conductive particles; and a metal layer disposed on the adhesive layer, in which the adhesive layer includes a first adhesive layer containing the conductive particles and an adhesive component, and a second adhesive layer containing an adhesive component.
[2] The wiring-forming member according to [1] described above, in which the metal layer, the second adhesive layer, and the first adhesive layer are laminated in this order.
[3] The wiring-forming member according to [1] or [2] described above, in which the second adhesive layer does not contain conductive particles.
[4] The wiring-forming member according to any one of [1] to [3] described above, in which a ratio of surface roughness Rz of a surface of the metal layer on the adhesive layer side to an average particle diameter of the conductive particles is 0.05 to 3.
[5] The wiring-forming member according to any one of [1] to [4] described above, in which the surface roughness Rz of the metal layer on the adhesive layer side is less than 20 μm.
[6] The wiring-forming member according to any one of [1] to [5] described above, further including a peeling film.
[7] A wiring-forming member, including: an adhesive layer containing conductive particles; and a metal layer disposed on the adhesive layer, in which the adhesive layer, in a thickness direction thereof, includes a first region containing the conductive particles and a first adhesive component, and a second region containing a second adhesive component.
[8] The wiring-forming member according to [7] described above, in which the metal layer, the second region, and the first region are provided adjacent to each other in this order.
[9] The wiring-forming member according to [7] or [8] described above, in which the second region does not contain conductive particles.
[10] The wiring-forming member according to any one of [7] to [9] described above, in which a ratio of surface roughness Rz of a surface of the metal layer on the adhesive layer side to an average particle diameter of the conductive particles is 0.05 to 3.
[11] The wiring-forming member according to any one of [7] to described above, in which the surface roughness Rz of the surface of the metal layer on the adhesive layer side is less than 20 μm.
[12] The wiring-forming member according to any one of [7] to described above, further including a peeling film.
[13] A wiring-forming member in which an adhesive layer containing conductive particles and a metal layer are separately provided, and the adhesive layer is adherable to the metal layer at the time of use, in which the adhesive layer includes a first adhesive layer containing the conductive particles and an adhesive component, and a second adhesive layer containing an adhesive component.
[14] The wiring-forming member according to described above, in which the second adhesive layer does not contain conductive particles.
[15] A wiring-forming member in which an adhesive layer containing conductive particles and a metal layer are separately provided, and the adhesive layer is adherable to the metal layer at the time of use, in which the adhesive layer includes a first region containing the conductive particles and a first adhesive component, and a second region containing a second adhesive component.
[16] The wiring-forming member according to described above, in which the second region does not contain conductive particles.
[17] A wiring layer forming method, including: a step of preparing the wiring-forming member according to any one of [1] to described above; a step of preparing a base material on which wiring is formed; a step of disposing the wiring-forming member on a surface of the base material on which the wiring is formed such that the adhesive layer faces the base material to cover the wiring; a step of thermocompression-bonding the wiring-forming member to the base material; and a step of performing a patterning treatment on the metal layer.
[18] A wiring-formed member, including: a base material including wiring; and a cured product of the wiring-forming member according to any one of [1] to described above, which is disposed on the base material to cover the wiring, in which the wiring, and the metal layer of the wiring-forming member or another wiring formed from the metal layer are electrically connected.

### EXAMPLES

Hereinafter, the present disclosure will be described in more detail by Examples, but the present disclosure is not limited to Examples.

### <Preparation of Materials>

As an adhesive component, the following thermosetting components and fillers were prepared.

### (Thermosetting Component)

Epoxy resin A: NC-3000H (a biphenyl novolac-type epoxy resin, manufactured by Nippon Kayaku Co., Ltd., product name, epoxy equivalent: 289 g/eq)

Phenol resin A: KA-1165 (a cresol novolac-type phenol resin, manufactured by DIC Corporation, product name, hydroxyl equivalent: 119 g/eq). Note that, the hydroxyl equivalent of the phenol resin was obtained by the following measurement method.

Curing accelerator A: G-8009L (isocyanate-masked imidazole, manufactured by DKS Co. Ltd., product name)

### (Filler)

Silica particles A: SC-2050 (KC) (fused spherical silica, an average particle diameter of 0.5 μm, manufactured by ADMATECHS COMPANY LIMITED, product name)

### [Measurement Method for Hydroxyl Equivalent]

1 g of a sample was precisely weighed into a round-bottom flask, and 5 mL of a test solution of an acetic acid anhydride and pyridine was accurately weighed thereto. Next, an air cooler was attached to the flask, and heating was performed at 100° C. for 1 hour. After cooling the flask, 1 mL of water was added, and the flask was heated again at 100° C. for 10 minutes. After cooling again the flask, the air cooler and the neck of the flask were washed with 5 mL of neutralized methanol, and 1 mL of a phenolphthalein reagent was added. For a solution obtained as described above, titration was performed using 0.1 mol/L of a potassium hydroxide/ethanol solution to obtain a hydroxyl value. From the obtained hydroxyl value, a hydroxyl equivalent (g/eq) was calculated in terms of a mass per 1 mol (1 eq) of a hydroxyl group.

As conductive particles, the followings were prepared.

### (Conductive Particles 1)

As conductive particles 1, gold-plated resin particles (resin material: a styrene-divinyl benzene copolymer), conductive particles with an average particle diameter of 20 μm and specific weight of 1.7 were prepared.

### (Conductive Particles 2)

As conductive particles 2, gold-plated resin particles (resin material: a styrene-divinyl benzene copolymer), conductive particles with an average particle diameter of 10 μm and specific weight of 1.8 were prepared.

### <Production of Adhesive Layer>

(PET Film with Adhesive Layer R-1)

23.12 g of an epoxy resin A, 9.52 g of a phenol resin A, and 0.065 g of a curing accelerator A were dissolved in 13.05 g of methyl ethyl ketone (MEK), and then, 12.56 g of silica particles A and 17.03 g of the conductive particles 1 were added to prepare a coating liquid for forming an adhesive layer. Such a coating liquid was applied to a PET film with a thickness of 50 μm using a coating apparatus (manufactured by Yasui Seiki Company, Ltd., product name: Precision Coater), and was subjected to hot-air drying at 160° C. for 10 minutes to produce an adhesive layer R-1 in which the conductive particles with a thickness of 20 μm were contained in an adhesive component on the PET film.

(PET Film with Adhesive Layer R-2)

As with the production of the PET film with the adhesive layer R-1, except that the thickness of the adhesive layer was changed to 25 μm, an adhesive layer R-2 was produced on the PET film.

(PET Film with Adhesive Layer R-3)

As with the production of the PET film with the adhesive layer R-1, except that the thickness of the adhesive layer was changed to 30 μm, an adhesive layer R-3 was produced on the PET film.

(PET Film with Adhesive Layer R-4)

As with the production of the PET film with the adhesive layer R-1, except that the conductive particles 2 were used instead of the conductive particles 1, and the thickness of the adhesive layer was changed to 14 μm, an adhesive layer R-4 was produced on the PET film.

(PET Film with Adhesive Layer R-5)

As with the production of the PET film with the adhesive layer R-1, except that the conductive particles 2 were used instead of the conductive particles 1, and the thickness of the adhesive layer was changed to 10 μm, an adhesive layer R-5 was produced on the PET film.

(Copper Foil with Adhesive Layer S-1)

23.12 g of an epoxy resin A, 9.52 g of a phenol resin A, and 0.065 g of a curing accelerator A were dissolved in 13.05 g of methyl ethyl ketone (MEK), and then, 12.56 g of silica particles A was added to prepare a coating liquid for forming an adhesive layer.

Such a coating liquid was applied to one surface (surface roughness Rz: 3.0 μm) of a copper foil (manufactured by MITSUI MINING & SMELTING CO., LTD., product name: “3EC-M3-VLP”, thickness: 12 μm) using a coating apparatus (manufactured by Yasui Seiki Company, Ltd., product name: Precision Coater), and was subjected to hot-air drying at 160° C. for 10 minutes to produce an adhesive layer S-1 with a thickness of 5 μm on the copper foil.

(Copper Foil with Adhesive Layer S-2)

As with the production of the copper foil with the adhesive layer S-1, except that the thickness of the adhesive layer was changed to 10 μm, an adhesive layer S-2 was produced on the copper foil.

(Copper Foil with Adhesive Layer S-3)

As with the production of the copper foil with the adhesive layer S-1, except that the thickness of the adhesive layer was changed to 6 μm, an adhesive layer S-2 was produced on the copper foil.

(Copper Foil with Adhesive Layer R-1)

23.12 g of an epoxy resin A, 9.52 g of a phenol resin A, and 0.065 g of a curing accelerator A were dissolved in 13.05 g of methyl ethyl ketone (MEK), and then, 12.56 g of silica particles A and 17.03 g of the conductive particles 1 were added to prepare a coating liquid for forming an adhesive layer. Such a coating liquid was applied to one surface (surface roughness Rz: 3.0 μm) of a copper foil (manufactured by MITSUI MINING & SMELTING CO., LTD., product name: “3EC-M3-VLP”, thickness: 12 μm) using a coating apparatus (manufactured by Yasui Seiki Company, Ltd., product name: Precision Coater), and was subjected to hot-air drying at 160° C. for 10 minutes to produce an adhesive layer R-1 in which the conductive particles with a thickness of 20 μm were contained in an adhesive component on the copper foil.

(Copper Foil with Adhesive Layer R-2)

As with the production of the copper foil with the adhesive layer R-1, except that the thickness of the adhesive layer was changed to 25 μm, an adhesive layer R-2 was produced on the copper foil.

(Copper Foil with Adhesive Layer R-3)

As with the production of the copper foil with the adhesive layer R-1, except that the thickness of the adhesive layer was changed to 30 μm, an adhesive layer R-3 was produced on the copper foil.

(Copper Foil with Adhesive Layer R-4)

As with the production of the copper foil with the adhesive layer R-1, except that the conductive particles 2 were used instead of the conductive particles 1, and the thickness of the adhesive layer was changed to 14 μm, an adhesive layer R-4 was produced on the copper foil.

(Copper Foil with Adhesive Layer R-6)

As with the production of the copper foil with the adhesive layer R-1, except that the conductive particles 2 were used instead of the conductive particles 1, and the thickness of the adhesive layer was changed to 20 μm, an adhesive layer R-6 was produced on the copper foil.

(PET Film with Adhesive Layer S-1)

23.12 g of an epoxy resin A, 9.52 g of a phenol resin A, and 0.065 g of a curing accelerator A were dissolved in 13.05 g of methyl ethyl ketone (MEK), and then, 12.56 g of silica particles A was added to prepare a coating liquid for forming an adhesive layer.

Such a coating liquid was applied to a PET film with a thickness of 50 μm using a coating apparatus (manufactured by Yasui Seiki Company, Ltd., product name: Precision Coater), and was subjected to hot-air drying at 160° C. for 10 minutes to produce an adhesive layer S-1 with a thickness of 5 μm on the PET film.

(PET Film with Adhesive Layer S-3)

As with the production of the PET film with the adhesive layer S-1, except that the thickness of the adhesive layer was changed to 6 μm, an adhesive layer S-3 was produced on the PET film.

### <Production of Wiring-Forming Member-1>

### Example A-1

The PET film with the adhesive layer R-1 and the copper foil with the adhesive layer S-1 were bonded using a hot roll laminator (Leon13DX) in the condition of 70° C. and 1.0 m/min such that the respective adhesive layers were in contact with each other. As described above, a wiring-forming member having a structure in which a second adhesive layer (a second region) composed of the copper foil and the adhesive layer S-1, a first adhesive layer (a first region) composed of the adhesive layer R-1, and the PET film were sequentially laminated was produced.

### Example A-2

As with Example A-1, except that the PET film with the adhesive layer R-1 and the copper foil with the adhesive layer S-2 were bonded, a wiring-forming member having a structure a second adhesive layer (a second region) composed of the copper foil and the adhesive layer S-2, a first adhesive layer (a first region) composed of the adhesive layer R-1, and the PET film were sequentially laminated was produced.

### Example A-3

As with Example A-1, except that the PET film with the adhesive layer R-4 and the copper foil with the adhesive layer S-3 were bonded, a wiring-forming member having a structure in which a second adhesive layer (a second region) composed of the copper foil and the adhesive layer S-3, a first adhesive layer (a first region) composed of the adhesive layer R-4, and the PET film were sequentially laminated was produced.

### Example A-4

As with Example A-1, except that the PET film with the adhesive layer R-5 and the copper foil with the adhesive layer S-2 were bonded, a wiring-forming member having a structure in which a second adhesive layer (a second region) composed of the copper foil and the adhesive layer S-2, a first adhesive layer (a first region) composed of the adhesive layer R-5, and the PET film were sequentially laminated was produced.

### Comparative Example A-1

The copper foil with the adhesive layer R-1 was set as a wiring-forming member having a structure in which the copper foil and a first adhesive layer (a first region) composed of the adhesive layer R-1 were sequentially laminated.

### Comparative Example A-2

The copper foil with the adhesive layer R-2 was set as a wiring-forming member having a structure in which the copper foil and a first adhesive layer (a first region) composed of the adhesive layer R-2 were sequentially laminated.

### Comparative Example A-3

The copper foil with the adhesive layer R-3 was set as a wiring-forming member having a structure in which the copper foil and a first adhesive layer (a first region) composed of the adhesive layer R-3 were sequentially laminated.

### Comparative Example A-4

The copper foil with the adhesive layer R-4 was set as a wiring-forming member having a structure in which the copper foil and a first adhesive layer (a first region) composed of the adhesive layer R-4 were sequentially laminated.

### Comparative Example A-5

The copper foil with the adhesive layer R-6 was set as a wiring-forming member having a structure in which the copper foil and a first adhesive layer (a first region) composed of the adhesive layer R-6 were sequentially laminated.

### <Measurement of Connection Resistance Value and Evaluation of Cross-Sectional Structure>

### (Production of Evaluation Sample)

The wiring-forming member was attached to a circuit board (PWB) including three copper circuits with a line width of 1000 μm, a pitch of 10000 μm, and a thickness of 15 μm on an epoxy substrate with a glass cloth from the first adhesive layer (the first region) side (after peeling the PET film in the case of including the PET film). This was heated and pressurized at 180° C. and 2 MPa for 60 minutes using a thermocompression bonding apparatus (heating type: constant heating, manufactured by Toray Engineering Co., Ltd.) and connected over a width of 2 mm to produce a connected body.

A resist was formed on the produced connected body, and this was immersed in an etching solution and oscillated. The etching solution was adjusted with copper chloride: 100 g/L and hydrochloric acid: 100 ml/L. When a predetermined copper foil portion was removed, washing was performed with pure water. After that, the resist was peeled, and an evaluation sample on which a predetermined wiring pattern was formed was obtained.

### [Measurement of Connection Resistance Value]

A resistance value between the formed wiring pattern and the copper circuit on the substrate was measured with a multimeter immediately after adhesion. The resistance value was represented as the average of 37 resistance points between the wiring pattern and the copper circuit on the board.

### [Evaluation of Cross-Sectional Structure]

For the produced evaluation sample, the cross-sectional surface was observed by the following method, a distance A between the wiring pattern and the substrate (for example, a distance between 20f and 30 in (b) in FIG. 6), and a shortest distance B between the wiring pattern and the conductive particles (for example, a shortest distance between 20f and 12 in (b) in FIG. 6) were measured.

### (Observation Method for Cross-Sectional Surface)

First, the evaluation sample was cast with a resin composition consisting of 100 g of a bisphenol A-type epoxy resin (product name: JER811, manufactured by Mitsubishi Chemical Corporation) and 10 g of a curing agent (product name: Epomount Curing Agent, manufactured by Refine Tec Ltd.). After that, the cross-sectional surface was polished using a polisher, and the cross-sectional surface was observed using a scanning electron microscope (SEM, product name: SE-8020, manufactured by Hitachi High-Tech Science Corporation).

In a case where the shortest distance B is large or a ratio of the shortest distance B to the distance A is large, it is easy to ensure a distance in which the conduction by the conductive particles does not occur between the wiring pattern, in which conductive connection is not desired, and the copper circuit, and it is easy to ensure insulating reliability in the thickness direction of the adhesive layer. In addition, in a case where the shortest distance B is large, or the shortest distance B is larger than the distance A, it is possible to reduce the number of conductive particles that do not contribute to the conduction in which the conductive particles are in contact with the wiring pattern (or a portion in the wiring pattern, which is not conductively connected), which is advantageous from the viewpoint of suppressing a transmission loss of the wiring.

TABLE 1

| | | | | | | | | Cross-sectional structure | |
|---|---|---|---|---|---|---|---|---|---|
| | | | | | | | | | Shortest |
| | | First adhesive layer | | | | | | | distance |
| | | | | Average | | | | Distance | between |
| | Total | | | particle | | | | between | wiring |
| | thickness of | | | diameter of | | | Connection | wiring | pattern and |
| | adhesive | | | conductive | Second adhesive layer | | resistance | pattern and | conductive |
| | layer | | Thickness | particles | | Thickness | value | substrate | particles |
| | (μm) | No. | (μm) | (μm) | No. | (μm) | (mΩ) | (μm) | (μm) |
| Example A-1 | 25 | R-1 | 20 | 20 | S-1 | 5 | 2.2 | 22 | 2 |
| Example A-2 | 30 | R-1 | 20 | 20 | S-2 | 10 | 3.0 | 24 | 4 |
| Example A-3 | 20 | R-4 | 14 | 10 | S-3 | 6 | 1.8 | 22 | 3 |
| Example A-4 | 20 | R-5 | 10 | 10 | S-2 | 10 | 2.3 | 23 | 5 |
| Comparative | 20 | R-1 | 20 | 20 | — | — | 1.9 | 20 | 0 |
| Example A-1 | | | | | | | | | |
| Comparative | 25 | R-2 | 25 | 20 | — | — | 5.2 | 23 | 0 |
| Example A-2 | | | | | | | | | |
| Comparative | 30 | R-3 | 30 | 20 | — | — | 10.2 | 26 | 0 |
| Example A-3 | | | | | | | | | |
| Comparative | 14 | R-4 | 14 | 10 | — | — | 1.8 | 16 | 0 |
| Example A-4 | | | | | | | | | |
| Comparative | 20 | R-6 | 20 | 10 | — | — | 9.8 | 20 | 0 |
| Example A-5 | | | | | | | | | |

### <Production of Wiring-Forming Member-2>

### Example B-1

The copper foil with the adhesive layer R-1 and the PET film with the adhesive layer S-1 were bonded using a hot roll laminator (Leon13DX) in the condition of 70° C. and 1.0 m/min such that the respective adhesive layers were in contact with each other. As described above, a wiring-forming member having a structure in which a first adhesive layer (a first region) composed of the copper foil and the adhesive layer R-1, a second adhesive layer (a second region) composed of the adhesive layer S-1, and the PET film were sequentially laminated was produced.

### Example B-2

As with Example B-1, except that the copper foil with the adhesive layer R-4 and the PET film with the adhesive layer S-3 were bonded, a wiring-forming member having a structure in which a first adhesive layer (a first region) composed of the copper foil and the adhesive layer R-4, a second adhesive layer (a second region) composed of the adhesive layer S-3, and the PET film were sequentially laminated was produced.

### Examples A-1 to A-4

As described above, wiring-forming members of Examples A-1 to A-4 were produced.

### <Measurement of Connection Resistance Value>

As described above, an evaluation sample was produced, and a connection resistance value was measured. Note that, the wiring-forming members of Examples B-1 and B-2 were attached onto the epoxy substrate from the second adhesive layer (the second region) side after peeling the PET film.

### <Evaluation of Embedability>

### (Production of Evaluation Sample)

The wiring-forming member with a size of 250 mm×250 mm was attached to a circuit board (PWB) including a copper circuit with 1.0 mmϕ, a pitch of 1.5 mm, and a thickness of 12 μm from the second adhesive layer (the second region) side (after peeling the PET film in the case of including the PET film) on the epoxy substrate with a glass cloth. This was heated and pressurized at 180° C. and 2 MPa for 60 minutes using a thermocompression bonding apparatus and connected to produce a connected body. Note that, the wiring-forming members of Examples A-1 to A-4 were attached onto the epoxy substrate from the first adhesive layer (the first region) side after peeling the PET film.

A sample in which a resist was formed on the produced connected body was immersed in an etching solution and oscillated. The etching solution was prepared with copper chloride: 100 g/L and hydrochloric acid: 100 ml/L. When a predetermined copper foil portion was removed, washing was performed with pure water. After that, the resist was peeled, and an evaluation sample on which a predetermined wiring pattern was formed was obtained.

### [Embeddability]

For the produced evaluation sample, the appearance was visually observed, the presence or absence of air bubbles or peeling was observed, and embeddability was evaluated in accordance with the following evaluation criterion.

### (Evaluation Criterion)

A: In the evaluation sample, the air bubbles or the peeling are not observed in an area range of 90% or more.
B: In the evaluation sample, the air bubbles or the peeling are not observed in an area range of 70% or more and less than 90%.
C: In the evaluation sample, the air bubbles or the peeling are observed in an area range of greater than 30% or the entire area.

TABLE 2

| | | First adhesive layer | | | | | | |
|---|---|---|---|---|---|---|---|---|
| | | | | Average | | | | |
| | Total | | | particle | | | | |
| | thickness of | | | diameter of | | | Connection | |
| | adhesive | | | conductive | Second adhesive layer | | resistance | |
| | layer | | Thickness | particles | | Thickness | value | |
| | (μm) | No. | (μm) | (μm) | No. | (μm) | (mΩ) | Embedability |
| Example B-1 | 25 | R-1 | 20 | 20 | S-1 | 5 | 2.5 | A |
| Example B-2 | 20 | R-4 | 14 | 10 | S-3 | 6 | 1.8 | A |
| Example A-1 | 25 | R-1 | 20 | 20 | S-1 | 5 | 2.2 | B |
| Example A-2 | 30 | R-1 | 20 | 20 | S-2 | 10 | 3.0 | B |
| Example A-3 | 20 | R-4 | 14 | 10 | S-3 | 6 | 1.8 | B |
| Example A-4 | 20 | R-5 | 10 | 10 | S-2 | 10 | 2.3 | B |

As shown in Table 2, according to the wiring-forming members of Examples B-1 and B-2, it is found that it is also possible to suppress the occurrence of the air bubbles or the like while ensuring sufficient conduction between the wirings.

### REFERENCE SIGNS LIST

1: wiring-forming member, la: wiring layer, 1b: wiring-formed member, 3: wiring-forming member, 10: adhesive layer, 10a: first surface, 10b: second surface, 15: first adhesive layer, 16: second adhesive layer, 12, 12a, 12b, 12c: conductive particles, 14: adhesive layer, 17: adhesive layer, 18a, 18b: adhesive layer, 20: metal layer, 20a: first surface, 20b: second surface, 40: adhesive layer, 40a: first surface, 40b: second surface.

1. A wiring-forming member, comprising:
an adhesive layer containing conductive particles; and
a metal layer disposed on the adhesive layer,
wherein the adhesive layer includes a first adhesive layer containing the conductive particles and an adhesive component, and a second adhesive layer containing an adhesive component.

2. The wiring-forming member according to claim 1,
wherein the metal layer, the second adhesive layer, and the first adhesive layer are laminated in this order.

3. The wiring-forming member according to claim 1,
wherein the second adhesive layer does not contain conductive particles.

4. The wiring-forming member according to claim 1,
wherein a ratio of surface roughness Rz of a surface of the metal layer on the adhesive layer side to an average particle diameter of the conductive particles is 0.05 to 3.

5. The wiring-forming member according to claim 1,
wherein surface roughness Rz of a surface of the metal layer on the adhesive layer side is less than 20 μm.

6. The wiring-forming member according to claim 1, further comprising a peeling film.

7. A wiring-forming member, comprising:
an adhesive layer containing conductive particles; and
a metal layer disposed on the adhesive layer,
wherein the adhesive layer, in a thickness direction thereof, includes a first region containing the conductive particles and a first adhesive component, and a second region containing a second adhesive component.

8. The wiring-forming member according to claim 7,
wherein the metal layer, the second region, and the first region are provided adjacent to each other in this order.

9. The wiring-forming member according to claim 7,
wherein the second region does not contain conductive particles.

10. The wiring-forming member according to claim 7,
wherein a ratio of surface roughness Rz of a surface of the metal layer on the adhesive layer side to an average particle diameter of the conductive particles is 0.05 to 3.

11. The wiring-forming member according to claim 7,
wherein surface roughness Rz of a surface of the metal layer on the adhesive layer side is less than 20 μm.

12. The wiring-forming member according to claim 7, further comprising
a peeling film.

13. A wiring-forming member in which an adhesive layer containing conductive particles and a metal layer are separately provided, and the adhesive layer is adherable to the metal layer at the time of use,
wherein the adhesive layer includes a first adhesive layer containing the conductive particles and an adhesive component, and a second adhesive layer containing an adhesive component.

14. The wiring-forming member according to claim 13,
wherein the second adhesive layer does not contain conductive particles.

15. A wiring-forming member in which an adhesive layer containing conductive particles and a metal layer are separately provided, and the adhesive layer is adherable to the metal layer at the time of use,
wherein the adhesive layer includes a first region containing the conductive particles and a first adhesive component, and a second region containing a second adhesive component.

16. The wiring-forming member according to claim 15,
wherein the second region does not contain conductive particles.

17. A wiring layer forming method, comprising:
a step of preparing the wiring-forming member according to claim 1;
a step of preparing a base material on which wiring is formed;
a step of disposing the wiring-forming member on a surface of the base material on which the wiring is formed such that the adhesive layer faces the base material to cover the wiring;
a step of thermocompression-bonding the wiring-forming member to the base material; and
a step of performing a patterning treatment on the metal layer.

18. A wiring-formed member, comprising:
a base material including wiring; and
a cured product of the wiring-forming member according to claim 1, which is disposed on the base material to cover the wiring,
wherein the wiring, and the metal layer of the wiring-forming member or another wiring formed from the metal layer are electrically connected.
